(19) United States
(12) Patent Application Publication
(10) Pub. No.: US 2013/0098442 A1
(43) Pub. Date: Apr. 25, 2013

(54) NEAR FIELD LIGHT-SOURCE TWO-DIMENSIONAL ARRAY AND PROCESS FOR PRODUCING THE SAME, TWO-DIMENSIONAL ARRAY-TYPE LOCALIZED SURFACE PLASMON RESONATOR, SOLAR CELL, OPTICAL SENSOR, AND BIOSENSOR

(71) Applicants: Takao Ochiai, Ibaraki (JP); Katsuhiro Isozaki, Ibaraki (JP); Tomoya Taguchi, Ibaraki (JP); Kohichi Nittoh, Ibaraki (JP); Kazushi Miki, Ibaraki (JP)

(72) Inventors: Takao Ochiai, Ibaraki (JP); Katsuhiro Isozaki, Ibaraki (JP); Tomoya Taguchi, Ibaraki (JP); Kohichi Nittoh, Ibaraki (JP); Kazushi Miki, Ibaraki (JP)

(21) Appl. No.: 13/643,563

(22) PCT Filed: Mar. 3, 2011
(86) PCT No.: PCT/JP2011/054963

§ 371 Date: Jan. 2, 2013

(30) Foreign Application Priority Data
Apr. 27, 2010 (JP) 2010101986

(51) Int. Cl. G02B 5/00; H01L 31/0216; C25D 13/00

(52) U.S. Cl. CPC G02B 5/008; C25D 13/00; H01L 31/02168
USPC 136/257; 362/235; 204/471; 204/489

(57) ABSTRACT

The invention provides a large-area near field light two-dimensional array firmly immobilized on a substrate, and an inexpensive method for producing the array. The object is attained by using a near field light two-dimensional array 50 that comprises an electroconductive member 6, an immobilizing layer 2 formed on one surface of the electroconductive member 6 and a plurality of light-scattering particles 4 arranged on one surface 2a of the immobilizing layer 2, and enables in-plane light emission through the near field light from the light-scattering particles 4, in which the light-scattering particles 4 have a particle size of from 1 to 100 nm or less, the light-scattering particles 4 are arrayed in a lattice arrangement and spaced equally from each other, the distance between the adjacent light-scattering particles 4 is not larger than the particle size, and the localized surface plasmon of the light-scattering particles 4 can resonate with external light.

### TECHNICAL FIELD

The present invention relates to a near field light source two-dimensional array and its production method, and to a two-dimensional array-type localized surface plasmon resonator, a solar cell, an optical sensor and a biosensor.

### BACKGROUND ART

Heretofore, for near field light, a type of point source for light generation through a hole having a size of not more than the light wavelength as formed at the tip of a metal-coated optical fiber has been energetically studied and developed to support the development of techniques of immersion lithography and near field microscopy.

Regarding near field light sources, in principle, only those of a nanoscale size could be realized. However, two-dimensional arraying of a large number of near field light sources is expected to be applicable to photochemical reactors, optical devices, high sensitivity sensors, etc.

The structure also functions as a local plasmon resonator. The near field light generated through resonation with light around resonant frequencies could again return back to the transmitted radiation. The local plasmon resonator is expected to be applicable to photochemical reactors, solar cells, high sensitivity optical sensors, high sensitivity biosensors, etc.

Metal nanoparticles having a particle size of from 1 to 100 nm can generate local light (hereinafter, near field light) of which the size corresponds to the radius of the particle. Accordingly, a metal nanoparticle array structure where metal nanoparticles are two-dimensionally arrayed on a substrate in such a manner that the distance between the metal nanoparticles could be from 1 to 10 nm can generate a large electric field or an extremely bright near field light in the gaps among the metal nanoparticles. In this, the near field light propagates along the surfaces of the metal nanoparticles or the like scatters whilst ordinary light propagates in air.

For applying the metal nanoparticle array structure to light waveguides, photochemical reactors, optical devices or high sensitivity sensors, it is necessary to use a metal nanoparticle array structure where the size and the shape of the metal nanoparticles and also the distance between the metal nanoparticles are well uniformly controlled, for which, therefore, well controlling the size and the shape of the metal nanoparticles and also the distance between the metal nanoparticles will be a technical key point.

Some reports have already been made relating to the technique of producing a metal nanoparticle array structure. For example, nanosphere lithography (Non-Patent Documents 1 to 3) and electron beam lithography (Non-Patent Document 4) are already-existing techniques, which, however, have some problems in that the lithography apparatus is expensive and a large-scale structure is difficult to produce.

Production according to a self-organizing method has been tried. As a method of using an external pressure, there are known a Langmuir method (Non-Patent Documents 5 to 8), a Langmuir-Blodgett method (Non-Patent Documents 9 to 10), a dip coating method (Non-Patent Document 11), use of solid-liquid interface (Patent Document 1). As a method of using an external field, there are known an electrophoresis method (Non-Patent Document 13, Patent Document 3), and a solvent evaporation method (Non-Patent Document 12, Patent Document 2). However, these methods do not have any strong immobilizing means such as chemical bond or the like between the metal nanoparticle array structure and the immobilizing substrate, and are therefore problematic in that the metal nanoparticle array structure would readily peel away from the immobilizing substrate.

Regarding the technique of note for fixation on a substrate such as chemical bond or the like, there are known a thiol bond (Non-Patent Documents 14 and 15), a CN bond (Non-Patent Document 16), and a coordinate bond (Non-Patent Documents 17 to 18). According to these methods, however, a metal nanoparticle array structure having a high coverage is not obtained.

The coverage means the proportion of the area occupied by light-scattering particle arrays within a given area.

Of the above, the lithographic method is the most ideal except for the cost phase. FIG. 26 is a schematic view showing a gold nanoblock two-dimensional array structure formed through lithography.

As shown in FIG. 26, in the gold nanoblock two-dimensional array structure, gold blocks of 100 nm×100 nm are two-dimensionally arrayed via a gap distance of not more than 5 nm. An array has been substantiated (near field light two-dimensional array), in which gold blocks are irradiated with a polarized light from an external light source to generate a near field light and in which the near field light is enhanced only in the polarization direction of the light source (Non-Patent Document 19).

However, the gold nanoblock two-dimensional array structure is a near field light two-dimensional array in which the near field light is enhanced only in the polarization direction of the light source, and therefore the structure could not provide an in-plane uniform near field light and the intensity of the light given by the structure is not sufficient.

In addition, there are other problems in that a near field light two-dimensional array could not be produced inexpensively since the above uses an electron beam lithographic method, and that only a near field light two-dimensional array having a size smaller than an area of 300 μm×300 μm could be produced with a production accuracy of 5 nm×5 nm. Further, the gold nanoblock two-dimensional array structure has still another problem in that its fixation on the substrate thereof is weak, and, when used in a solution or a fluid, the structure is readily peeled off from the substrate.

### PRIOR ART DOCUMENTS

Patent Document 1: JP-A 2006-192398
Patent Document 2: JP-A 2007-313642
Patent Document 3: JP-A 2009-6311
Patent Document 4: JP-A 2006-250668
Non-Patent Document 1: Wang, W.; Wang, Y.; Dai, Z.; Sun, Y.; Sun, Y. Appl. Surface Sci. 2007, 253, 4673-4676.
Non-Patent Document 2: Shen, H.; Cheng, B.; Lu, G.; Ning, T.; Guan, D.; Zhou, Y.; Chen, Z., Nanotechnology, 2006, 17, 4274-4277.
Non-Patent Document 3: Tan, B. J. Y.; Sow, C. H.; Koh, T. S.; Chin, K. C.; Wee, A. T. S.; Ong, C. K., J. Phys. Chem. B 2005, 109, 11100-11109.
Non-Patent Document 4: Felidj, N.; Aubard, J.; Levi, G. Appl. Phys. Chem. 2003, 82, 3095-3097.
Non-Patent Document 5: Liao, J; Agustsson, J. S.; Wu, S.; Schoenenberger, C.; Calame, M.; Leroux, Y.; Mayor, M.; Jeannin, O.; Ran, Y.-F.; Liu, S.-X.; Decurtins, S, Nano Lett. 2010, 10, 759-764.
Non-Patent Document 6: Chiang, Y,-L; Chen, C.-W; Wang, C.-H.; Hsein, C.-Y; Chen, Y.-T; Appl. Phys. Lett., 2010, 96, 041904-1-041904-4.
Non-Patent Document 7: Kim, B.; Tripp, S. L.; Wei, A. J. Am. Chem. Soc. 2001, 123, 7955-7956.
Non-Patent Document 8: Kim, B.; Sadtler, B.; Tripp, S. L. Chem. Phys. Chem., 2001, 12, 743-745.
Non-Patent Document 9: Park, Y.-K.; Yoo, S.-H.; Park, S. Langmuir, 2008, 24, 4370-4375.
Non-Patent Document 10: Brown, J. J.; Porter, J. A.; Daghlian, C. P.; Gibson, U. J. Langmuir, 2001, 17, 7966-7969.
Non-Patent Document 11: Dai, C.-A.; Wu, Y.-L.; Lee, Y.-H.; Chang, C.-J.; Su, W.-F. J. Cryst. Growth, 2006, 288, 128-136.
Non-Patent Document 12: Wang, H.; Levin, C. S.; Halas, N. J. J. Am. Chem. Soc., 2005, 127, 14992-14993.
Non-Patent Document 13: Peng, Z.; Qu, X.; Dong, S. Langmuir, 2004, 20, 5-10.
Non-Patent Document 14: Kaminska, A.; Inya-Agha, O.; Forster, R. J.; Keyes, T. E. Phys. Chem. Chem. Phys., 2008, 10, 4172-4180.
Non-Patent Document 15: Grabar, K. C.; Smith, P. C.; Musick, M. D.; Davis, J. A.; Walter, D. G.; Jackson, M. A.; Guthrie, A. P.; Natan, M. J. J. Am. Chem. Soc., 1996, 118, 1148-1153.
Non-Patent Document 16: Chan, E. W. L.; Yu, L. Langmuir, 2002, 18, 311-313.
Non-Patent Document 17: Wanunu, M.; Popovitz-Biro, R.; Cohen, H.; Vaskevich, A.; Rubinstein, I. J. Am. Chem. Soc., 2005, 127, 9207-9215.
Non-Patent Document 18: Zamborini, F. P.; Hicks, J. F.; Murray, R. W. J. Am. Chem. Soc. 2000, 122, 4514-4515.
Non-Patent Document 19: T. Kawazoe, et al., Appl. Phys. Lett. 2001, 79, 1184.
Non-Patent Document 20: Hartling, T.; Alayerdyan, Y.; Hille, A; Wenzel, M. T.; Kall, L. M., Optics. Express, 2008, 16, 12362-12371.

### SUMMARY OF THE INVENTION

### Problems to be Solved by the Invention

The present invention has been accomplished for solving the problems with the prior art as above, and an object of the invention is to provide a near field light two-dimensional array firmly immobilized on a substrate and having a large area (area of at least 300 μm×300 μm), and to provide an inexpensive production method for the array.

### Means for Solving the Problems

The near field light two-dimensional array of the invention comprises an electroconductive member, an immobilizing layer formed on one surface of the electroconductive member and a plurality of light-scattering particles arranged on one surface of the immobilizing layer, and enables in-plane light emission through the near field light from the light-scattering particles, in which the light-scattering particles have a particle size of from 1 to 100 nm, the light-scattering particles are arrayed in a lattice arrangement and spaced equally from each other, the distance between the adjacent light-scattering particles is not larger than the particle size, and the localized surface plasmon of the light-scattering particles can resonate with external light.

In the near field light two-dimensional array of the invention, the thickness of the immobilizing layer is 10 nm or less.

In the near field light two-dimensional array of the invention, the distance between the light-scattering particles is from 1 to 10 nm.

In the near field light two-dimensional array of the invention, the light-scattering particles are bonded to each other via a modifying part arranged on the surface thereof.

In the near field light two-dimensional array of the invention, the light-scattering particles are metal nanoparticles.

In the near field light two-dimensional array of the invention, the metal nanoparticles are formed of gold.

In the near field light two-dimensional array of the invention, the modifying part is an organic molecule having a thiol group, and the thiol group is bonded to the metal nanoparticles.

In the near field light two-dimensional array of the invention, the organic molecule of the modifying part has an alkyl chain with from 6 to 20 carbon atoms.

In the near field light two-dimensional array of the invention, the immobilizing layer comprises an organic molecule having at least two thiol groups, at least one thiol group is arranged on both one surface and the other surface of the immobilizing layer, and the thiol group on the other surface is bonded to the electroconductive member.

In the near field light two-dimensional array of the invention, the organic molecule to constitute the immobilizing layer has an alkyl chain with from 6 to 20 carbon atoms.

In the near field light two-dimensional array of the invention, the electroconductive member is formed of gold.

In the near field light two-dimensional array of the invention, an external light source is disposed so that the external light can focus on the light-scattering particles.

The production method for the near field light two-dimensional array of the invention comprises a first step of dispersing light-scattering particles in a solvent to prepare a reaction liquid, filling a liquid tank with the reaction liquid, and arranging two electrodes oppositely to each other inside the liquid tank as immersed in the reaction liquid therein, and a second step of applying a voltage to the two electrodes from a power source connected to the two electrodes by wiring to thereby move the light-scattering particles in a mode of field migration, whilst moving the position of the liquid level of the reaction liquid relative to the electrode thereby forming a light-scattering particle array of the two-dimensionally arrayed light-scattering particles on the electrode.

In the production method for the near field light two-dimensional array of the invention, the moving speed of the position of the liquid level of the reaction liquid relative to the electrode is 0.02 mm/sec or less.

In the production method for the near field light two-dimensional array of the invention, a volatile solvent is used as the solvent in the first step, and the volatile solvent is evaporated away through voltage application in the second step.

In the production method for the near field light two-dimensional array of the invention, the volatile solvent is any of water, an alcohol, a ketone, an ester, a halogen-containing solvent, an aliphatic hydrocarbon or an aromatic hydrocarbon, or their mixture.

In the production method for the near field light two-dimensional array of the invention, the volatile solvent contains an inorganic salt, an organic salt or both of the two.

The two-dimensional array-type localized surface plasmon resonator of the invention is provided with the near field light two-dimensional array.

The solar cell of the invention is provided with the two-dimensional array-type localized surface plasmon resonator.

The light sensor of the invention is provided with the two-dimensional array-type localized surface plasmon resonator.

The biosensor of the invention is provided with the two-dimensional array-type localized surface plasmon resonator.

### Effect of the Invention

Since the near field light two-dimensional array of the invention comprises an electroconductive member, an immobilizing layer formed on one surface of the electroconductive member and a plurality of light-scattering particles arranged on one surface of the immobilizing layer, and enables in-plane light emission through the near field light from the light-scattering particles, in which the light-scattering particles have a particle size of from 1 to 100 nm, the light-scattering particles are arrayed in a lattice arrangement and spaced equally from each other, the distance between the adjacent light-scattering particles is not larger than the particle size, and the localized surface plasmon of the light-scattering particles can resonate with external light, the electroconductive member and the light-scattering particles are firmly bonded to each other via the immobilizing layer, and the localized surface plasmon of the light-scattering particles can resonate with external light. Consequently, the invention can provide the near field light two-dimensional array from which the intensity of the near field light is enhanced.

The production method for the near field light two-dimensional array of the invention comprises a first step of dispersing light-scattering particles in a solvent to prepare a reaction liquid, filling a liquid tank with the reaction liquid, and arranging two electrodes oppositely to each other inside the liquid tank as immersed in the reaction liquid therein, and a second step of applying a voltage to the two electrodes from a power source connected to the two electrodes by wiring to thereby move the light-scattering particles in a mode of field migration, whilst moving the position of the liquid level of the reaction liquid relative to the electrode thereby forming a light-scattering particle array of the two-dimensionally arrayed light-scattering particles on the electrode. Consequently, the production method can produce easily and inexpensively the near field light two-dimensional array having a large area (area of at least 300 μm×300 μm).

### BRIEF DESCRIPTION OF THE DRAWINGS

FIG. 1 shows one example of the near field light two-dimensional array of an embodiment of the invention. FIG. 1(a) is a perspective view; and FIG. 1(b) is a vertical cross-sectional view.

FIG. 2 is an enlarged plan view showing one example of a light-scattering particle array. This conceptually shows the near-field light generating region from the light-scattering particles.

FIG. 3 is an enlarged plan view showing another example of a light-scattering particle array. This conceptually shows the near-field light generating region from the light-scattering particles.

FIG. 4 shows enlarged views of a light-scattering particle array. FIG. 4(a) is an enlarged view of the part E in FIG. 2; and FIG. 4(b) is a cross-sectional view along the line F-F′ in FIG. 2. These conceptually show the near-field light generating region from the light-scattering particles.

FIG. 5 shows enlarged views of a light-scattering particle array.

FIG. 6 is a process chart showing the production method for the near field light two-dimensional array.

FIG. 7 is a SEM image of the light-scattering particle array of Example 1.

FIG. 8 is a SEM image of the light-scattering particle array of Example 2.

FIG. 9 is a SEM image of the light-scattering particle array of Example 3.

FIG. 10 shows small-angle scattering spectra of the light-scattering particle arrays of Examples 1 to 3.

FIG. 11 shows extinction spectra of the light-scattering particle arrays of Examples 1 to 3.

FIG. 12 shows extinction spectra of the light-scattering particle arrays of Example 2 and Example 4.

FIG. 13 is a SEM image of the metal nanoparticle array structure of Example 7.

FIG. 14 shows small-angle scattering spectra of the metal nanoparticle array structures of Examples 5 to 7.

FIG. 15 shows small-angle scattering spectra of the metal nanoparticle array structures of Example 6, Example 8 and Example 9.

FIG. 16 shows extinction spectra of the metal nanoparticle array structures of Examples 5 to 7.

FIG. 17 shows extinction spectra of the metal nanoparticle array structures of Example 6, Example 8 and Example 9.

FIG. 18 is a view showing photochemical reaction of HFDE.

FIG. 19 is NMR spectra of open-HFDE, close-HFDE and reaction product.

FIG. 20 shows absorption spectra of HFDE and extinction spectra of gold nanoparticle arrays.

FIG. 21 shows configuration views of the solar cell and the light sensor of Example 11 and Example 12.

FIG. 22 shows the characteristics of the solar cell of Example 11.

FIG. 23 shows the current-voltage characteristics of the optical sensor of Example 12.

FIG. 24 shows the sensitivity characteristic of the optical sensor of Example 12.

FIG. 25 is a configuration view of the biosensor of Example 13.

FIG. 26 is a plan view of a gold nanoblock two-dimensional array structure, showing a view of an existing case.

### MODE FOR CARRYING OUT THE INVENTION

### First Embodiment of the Invention

A near field light two-dimensional array of the first embodiment of the invention is described with reference to the attached drawings.

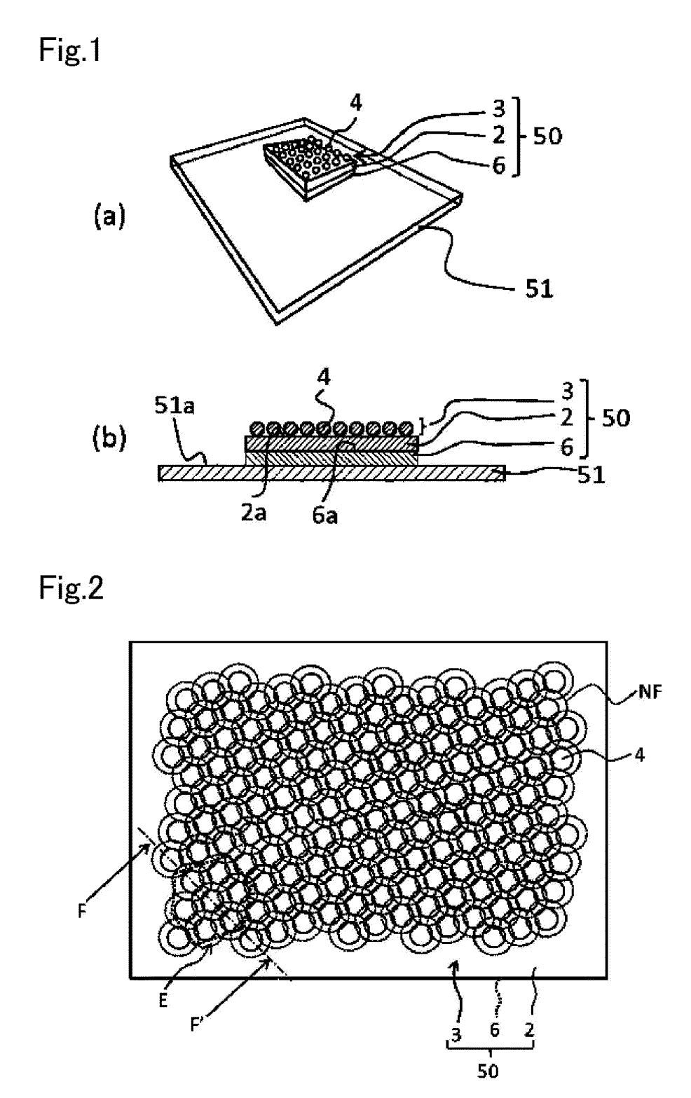

FIG. 1 shows one example of the near field light two-dimensional array of the first embodiment of the invention. FIG. 1(a) is a perspective view; and FIG. 1(b) is a vertical cross-sectional view.

As shown in FIG. 1, a near field light two-dimensional array 50 of the embodiment of the invention comprises an electroconductive member 6, an immobilizing layer 2 formed on one surface 6a of the electroconductive member 6, as immobilized thereon through chemical bonding, and a light-scattering particle array 3 immobilized on one surface 2a of the immobilizing layer 2 through chemical bonding. The light-scattering particle array 3 is so arrayed that the light-scattering particles 4 having a particle size of from 1 to 100 nm could be spaced equally from each other by the gap distance of not more than the particle size.

The electroconductive member 6 is formed on one surface 51a of the substrate 51. As the electroconductive member 6, usable is an electroconductive substrate formed of a metal material such as gold or the like. As the case may be, a thin film of gold or the like may be formed to be the electroconductive member 6. In the case, preferably, an insulating substrate such as a sapphire substrate, a quartz substrate, a glass substrate or the like is used as the substrate 51. This is because the substrate of the type has a high surface flatness and can form thereon the electroconductive member 6 flatly and at a high coverage.

FIG. 2 is an enlarged plan view showing one example of the light-scattering particle array 3. This conceptually shows the near field light NF from the light-scattering particles 4. As shown in FIG. 2, the light-scattering particle array 3 is a two-dimensional array of the light-scattering particles 4 arrayed regularly. The light-scattering particles 4 are arrayed on the entire surface of the immobilizing layer 2 with the same regularity. The near field light NF is regularly formed around each light-scattering particle 4, and therefore, the near field light is uniformly generated throughout on the entire surface of the immobilizing layer 2.

More concretely, by irradiating the light-scattering particles 4 having a size of from 1 to 100 nm with a light having a suitable wavelength distribution, the near field light NF is generated on the surface of the light-scattering particle 4. Accordingly, the near field light NF is generated uniformly through the entire surface of the immobilizing layer 2 from the light-scattering particle array 3. The size of the near field light NF is known to be around the diameter of the light-scattering particle. Here, the size of the near field light NF means the range which the near field light reaches from the surface of the light-scattering particle 4.

The light-scattering particle array 3 is not limited to such an ideal array.

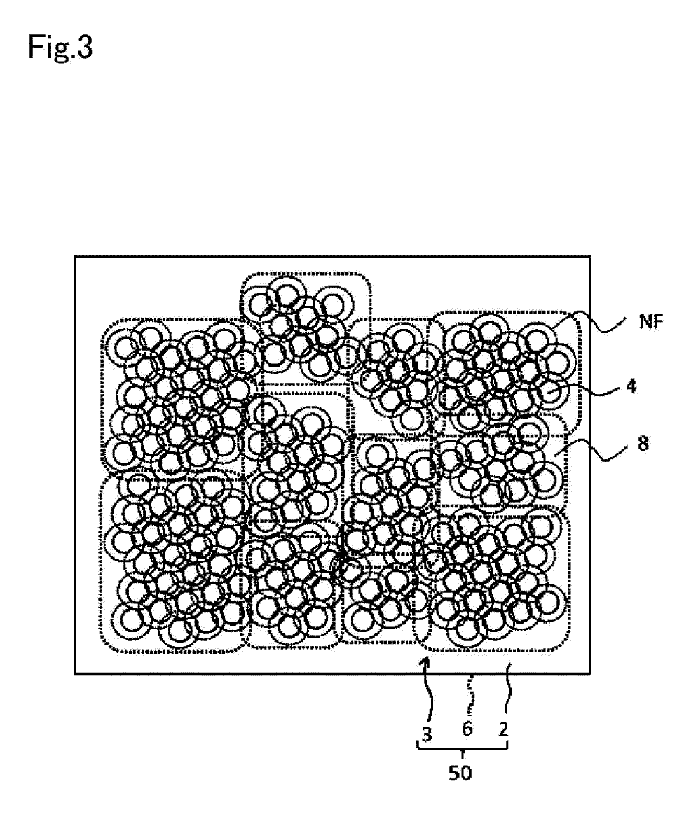

FIG. 3 is an enlarged view showing another example of the light-scattering particle array 3. As illustrated, the invention includes a case composed of multiple domains 8, in which each domain is a region of the light-scattering particle array 3 as arrayed with the same regularity. Also in the embodiment of the case, the light-scattering particles 4 are firmly bonded to the immobilizing layer 2 while the region not covered with the light-scattering particles 4 between the domains 8 can be reduced and the coverage with the particles can be increased.

The size of the domain 8 may be the first near region comprising only the nearest light-scattering particles 4 alone, or may be a second near region including up to the second near light-scattering particles 4, or may be a third near region including up to the third near light-scattering particles 4.

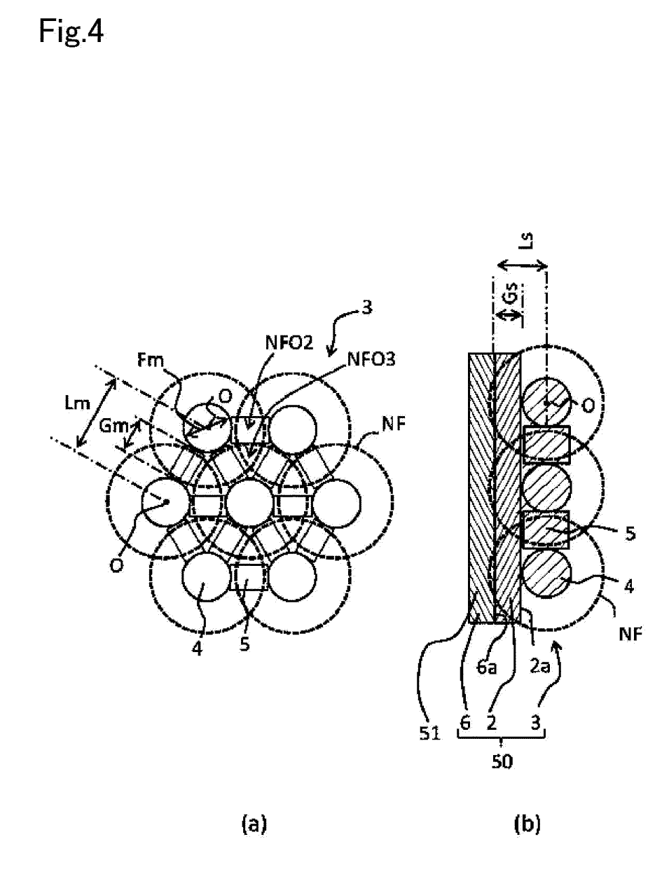

FIG. 4 shows enlarged views of the light-scattering particle array 3. FIG. 4(a) is an enlarged view of the part E in FIG. 2; and FIG. 4(b) is a cross-sectional view along the line F-F′ in FIG. 2.

As shown in FIG. 4, the light-scattering particles 4 having a particle size of Fm are bonded to each other through intermolecular interaction via the modifying part 5 therebetween. Accordingly, the distance (gap distance) Gm between the light-scattering particles 4 and the distance (particle-to-particle distance) Lm between the centers O of the adjacent light-scattering particles 4 are controlled to be nearly constant, and the light-scattering particles 4 are bonded firmly to each other. The thickness of the immobilizing layer (immobilizing layer thickness) Gs as well as the distance (particle-to-substrate distance) Ls from the center O of the light-scattering particle 4 to one surface 6a of the electroconductive member 6 are controlled to be nearly constant.

Preferred are metal nanoparticles, etc., and more preferred are gold nanoparticles. This is because gold can readily form uniformly-shaped and uniformly-sized particles and because the modifying part 5 of an organic molecule having a thiol group or the like can be readily bonded to gold.

However, not limited to the above, the light-scattering particles 4 may be any ones formed of a material having metallic properties or any ones coated with a light-scattering material such as metal or the like on the surface thereof. The inside of the particle may be a cavity or may also be an insulator or the like.

Preferably, the particle size Fm of the light-scattering particles 4 is from 1 to 100 nm, more preferably from 1 to 50 nm. Accordingly, the regularity of the light-scattering particles 4 in the light-scattering particle array 3 can be enhanced and the coverage with the particles can be increased.

Preferably, the gap distance Gm between the light-scattering particles 4 is not larger than the particle size Fm, and is preferably from 1 to 10 nm, more preferably from 1 to 5 nm. Accordingly, the light-scattering particles 4 can be bonded firmly to each other. In addition, the intensity of the near field light can be enhanced.

The light-scattering particles 4 generate localized surface plasmon on the surfaces thereof by the action of the external light applied thereto. The localized surface plasmon resonates with the photoelectric field of the external light thereby generating a near field light in a state of localized surface plasmon resonance. Accordingly, as shown in FIG. 4, the light-scattering particles 4 form the isotropic near field light NF around them. The spread of the near field light NF is around the particle size Fm or so. The light intensity of the near field light NF is the strongest on the side nearer to the light-scattering particle 4 and becomes gradually lower in the direction separating from the light-scattering particle 4.

The light-scattering particles 4 are arrayed in a lattice arrangement as spaced equally from each other, and therefore, between the adjacent light-scattering particles 4, there is formed a region NFO2 where two near field lights from the two light-scattering particles 4 overlap with each other. In the region surrounded by the three adjacent light-scattering particles 4, there is formed a region NFO3 where three near field lights from the three light-scattering particles 4 overlap with each other.

Between the adjacent light-scattering particles 4, a strong electric field-enhanced field is generated, and in the region NFO2 and the region NFO3, not only the intensity of the near field light is enhanced but also the electric field is enhanced.

Owing to the electromagnetic interaction between the light-scattering particles 4, red shift of the localized surface plasmon resonance frequency is occurred. In other words, the localized surface plasmon resonance frequency can be controlled by changing the size of the light-scattering particles 4 and the gap distance Gm between the light-scattering particles 4. When red shift of the localized surface plasmon resonance frequency is occurred by suitably adjusting the particle size Fm of the light-scattering particles 4 and the gap distance Gm between the light-scattering particles 4, then the localized surface plasmon resonance frequency can be thereby controlled.

As the modifying part 5, usable is an organic molecule having a thiol group such as an alkanethiol or the like. This is because, when gold nanoparticles or the like are used as the light-scattering particles 4, then the modifying part of the type can be firmly bonded to the surfaces thereof, and because the gap distance Gm between the light-scattering particles 4 can be kept nearly constant. Further, as the immobilizing layer 2, usable is an organic molecule having at least two thiol groups such as alkanediol or the like. This is because, when a gold material is sued as the electroconductive member 6, then the member can be firmly bonded to the surface of the layer via chemical bonding, and in addition, by aligning the organic molecules in such a manner that the molecular axis direction of the organic molecule could be vertical to one surface of the immobilizing layer 2, the length of the organic molecule may be the immobilizing layer thickness Gs, and the immobilizing layer thickness Gs can be kept nearly constant.

Preferably, the immobilizing layer thickness Gs is from 1 to 10 nm, more preferably from 1 to 5 nm. Inside the electroconductive member 6, localized surface plasmon resonance can be generated between the light-scattering particles 4 and the electroconductive member 6 to thereby enhance the intensity of the near field light from each light-scattering particle 4. When the immobilizing layer thickness Gs is at most 10 nm, then the effect can be enhanced more.

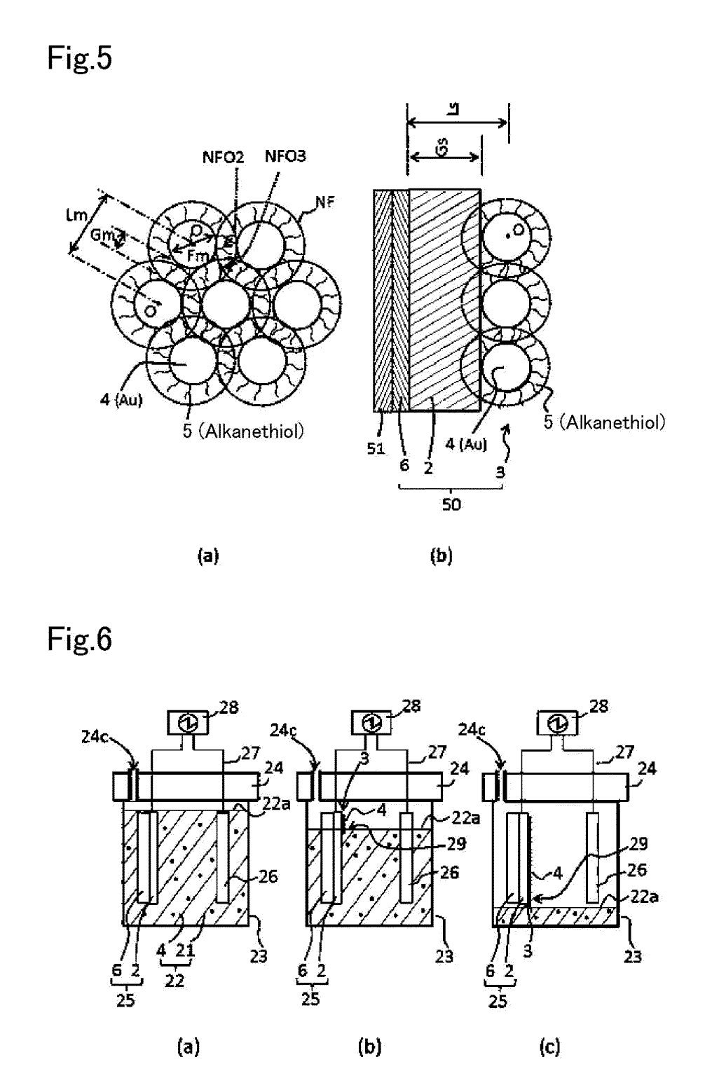

FIG. 5 includes views each showing one example of the light-scattering particle array 3, and are enlarged views more specifically showing the light-scattering particle array 3 shown in FIG. 4.

Au is used as the light-scattering particles 4, alkanethiol is used as the modifying part 5, and alkanediol (not shown) is used as the immobilizing layer 2. On the other side of the electroconductive member 6, arranged is a substrate 51 of an insulating substrate.

By controlling the length of the alkyl chain of the alkanethiol and that of the alkanediol, the gap distance Gm between the metal nanoparticles 4 and the particle-to-substrate distance Ls can be controlled.

### Second Embodiment of the Invention

Next described is a production method for the near field light two-dimensional array of the second embodiment of the invention.

FIG. 6 is a process chart showing one example of the production method for the near field light two-dimensional array of the second embodiment of the invention.

The production method for the near field light two-dimensional array comprises a first step of dispersing light-scattering particles in a solvent to prepare a reaction liquid, filling a liquid tank with the reaction liquid, and arranging two electrodes oppositely to each other inside the liquid tank as completely immersed in the reaction liquid therein, and a second step of applying a voltage to the two electrodes from a power source connected to the two electrodes by wiring to thereby move the light-scattering particles in a mode of field migration, whilst moving the liquid level of the reaction liquid thereby forming light-scattering particle arrays of the two-dimensionally arrayed light-scattering particles on one surface of the electrode.

FIG. 6(a) is a cross-sectional view of the process at the end of the first step, in which the light-scattering particles 4 such as metal nanoparticles or the like are dispersed in the solvent 21 to prepare a reaction liquid 22, then the reaction liquid 22 is put into the liquid tank 23, and then two electrodes 25 and 26 are arranged inside the liquid tank 23 to face each other therein, as completely immersed in the reaction liquid 22.

As the solvent 21, used is a volatile solvent. The light-scattering particle 4 is previously covered with the modifying part 5 of an organic molecule. As one electrode 25, used is the electroconductive member 6 with the immobilizing layer 2 formed thereon. As the electroconductive member 6, used is an electroconductive substrate, and the substrate is so arranged that the immobilizing layer 2 faces the other electrode 26. The liquid level 22a of the reaction liquid 22 is set at such a position that the two electrodes 25 and 26 could be completely immersed in the reaction liquid 22.

Preferably, the volatile solvent 21 is any of water, alcohols, ketones, esters, halogen solvents, aliphatic hydrocarbons, or aromatic hydrocarbons, or their mixtures. Accordingly, the kinetic and thermodynamic parameters in forming the structure of the light-scattering particles 4 can be controlled.

Preferably, the volatile solvent 21 contains an inorganic salt or an organic salt, or both of the two. Accordingly, the force in electrophoresis of the light-scattering particles 4 given by the electric field can be controlled.

The second step is a step of evaporating the solvent 21 from the reaction liquid 22 with applying a voltage to the two electrodes 25 and 26 from the power source 28 via the wiring 27 to thereby make the direct current run through the reaction liquid 22. When the direct current is made to run through the reaction liquid 22, the charged light-scattering particles 4 in the reaction liquid 22 begin to move through field migration, and begin to get together around any one of the electrodes. For example, in case where negatively charged light-scattering particles 4 are used, they get together around the anode electrode having a positive potential opposite thereto. Accordingly, when one electrode 25 is used as the anode electrode, then the light-scattering particles 4 get together on the one electrode 25. In that manner, the matter as to whether the electroconductive member 6 on which light-scattering particle arrays are formed is an anode electrode or a cathode electrode is determined depending on the charge potential of the light-scattering particles 4.

The light-scattering particles 4 have an ionic energy of electric field×moving distance×charge valence. Accordingly, owing to the ionic energy, the light-scattering particles 4 are chemically adsorbed by the electroconductive member 6 having passed through the energy barrier. In the absence of the ionic energy, the member could not chemically adsorb the light-scattering particles having passed through the energy barrier, but could adsorb them merely physically.

FIG. 6(b) is a cross-sectional view of the process at the intermediate point of the second step.

As shown in FIG. 6(b), during voltage application, the volatile solvent 21 evaporated away through the hole 24c of the lid 24 to thereby lower the liquid level 22a of the reaction liquid 22. Accordingly, the part of the electroconductive member 6 on the side of the lid 24 is thereby exposed out of the liquid level 22a.

The part on one surface of the immobilizing layer 2 and near the liquid level 22a but exposed out of the liquid level 22a (hereinafter referred to as air-liquid interface 29), the concentration of the light-scattering particles 4 is saturated, thereby resulting in nucleation for the two-dimensional arrays of the supersaturated light-scattering particles 4. With the descending of the liquid level 22a, the air-liquid interface 29 also descends. Accordingly, the nucleation for the two-dimensional arrays of the light-scattering particles 4 gradually goes on from the side of the lid 24. Consequently, in case where the nucleation speed for the two-dimensional arrays of the light-scattering particles 4 is higher than the evaporation rate of the volatile solvent 21 in the reaction liquid 22, the coverage with the light-scattering particle arrays 3 could be nearly 100%. Accordingly, the light-scattering particle arrays 3 can be formed at such a high coverage on the immobilizing layer 2 on the exposed electroconductive member 6.

The volatilization rate of the volatile solvent can be controlled by controlling the fluid-dynamic resistance to be determined by the opening diameter and the length of the hole 24c and by the viscosity of the vapor of the volatile solvent (viscosity×length/opening diameter). Accordingly, the moving speed of the liquid level 22a can be thereby controlled.

Chemical adsorption of the light-scattering particles 4 by the immobilizing layer 2 occurs simultaneously with the nucleation for the two-dimensional arrays of the light-scattering particles 4. When the ionic energy is not too large, a sufficient period of time could be provided for securing the energetically-stable physical position necessary for nucleation prior to chemical adsorption, thereby satisfying both chemical adsorption and two-dimensional arraying.

FIG. 6(c) is a cross-sectional view of the process at the end of the second step. The electroconductive member 6 is completely above the liquid level 22a, and light-scattering particle arrays 3 are formed on the immobilizing layer 2 on the electroconductive member 6. Thus, the light-scattering particle arrays 3 with the light-scattering particles 4 firmly bonded to the immobilizing layer 2 at a high coverage are formed.

Further, after the second step, the nanoparticle arrays 3 on the immobilizing layer 2 on the electroconductive member 6 may be annealed at 40 to 70° C. Accordingly, the chemical bond between the light-scattering particles 4 and the immobilizing layer 2 can be thereby strengthened more. Subsequently, the surface of the electroconductive member 6 is washed with running water or ultrasonically washed in a suitable solvent to thereby remove the light-scattering particles 4 not chemically bonding to the electroconductive member 6. According to the method, therefore, a large-area near field light two-dimensional array (having an area of 300 μm×300 μm or more) can be produced easily and inexpensively.

The near field light two-dimensional array 50 of the embodiment of the invention comprises the electroconductive member 6, the immobilizing layer 2 formed on one surface 6a of the electroconductive member 6 and a plurality of light-scattering particles 4 arranged on one surface 2a of the immobilizing layer 2, and enables in-plane light emission through the near field light from the light-scattering particles 4, in which the light-scattering particles 4 have a particle size of from 1 to 100 nm or less, the light-scattering particles 4 are arrayed in a lattice arrangement and spaced equally from each other, the distance between the adjacent light-scattering particles 4 is not larger than the particle size, and the localized surface plasmon of the light-scattering particles 4 can resonate with external light. In the near field light two-dimensional array having the configuration as above, therefore, the light-scattering particles 4 are firmly bonded to the electroconductive member 6 via the immobilizing layer 2 so that the localized surface plasmon of the light-scattering particles 4 can resonate with external light. Accordingly, the invention provides the near field light two-dimensional array from which the intensity of the near field light in the region NFO2 and the region NFO3 is enhanced. In addition, the invention also provides the large-area near field light two-dimensional array (having an area of 300 μm×300 μm or more).

In the near field light two-dimensional array 50 of the embodiment of the invention, the thickness of the immobilizing layer 2 is at most 10 nm. In this, localized surface plasmon resonance can occur also in the electroconductive substrate 6 and between the light-scattering particles 4 and the electroconductive substrate 6, and the invention can therefore provide the near field light two-dimensional array in which the intensity of the near field light from each light-scattering particle 4 is enhanced more.

In the near field light two-dimensional array 50 of the embodiment of the invention, the distance between the light-scattering particles 4 is from 1 to 10 nm. Accordingly, the invention can provide the near field light two-dimensional array in which the intensity of the near field light in the region NFO2 and the region NFO3 is enhanced owing to the localized surface plasmon of the light-scattering particles 4 capable of resonating with external light.

In the near field light two-dimensional array 50 of the embodiment of the invention, the light-scattering particles 4 are bonded to each other via the modifying part arranged on the surface thereof. Accordingly, the invention can provide the near field light two-dimensional array in which the light-scattering particles 4 are firmly bonded to each other and the intensity of the near field light in the region NFO2 and the region NFO3 is enhanced.

In the near field light two-dimensional array 50 of the embodiment of the invention, the light-scattering particles 4 are metal nanoparticles. Accordingly, the invention can provide the near field light two-dimensional array in which the light-scattering particles 4 are arrayed at high regularity in the two-dimensional plane owing to the intermolecular force thereof, the gap distance Gm between the light-scattering particles 4 is made the same, the light-scattering particle arrays can be formed at a high coverage, the electroconductive member 6 and the light-scattering particles 4 are firmly bonded to each other via the immobilizing layer 2, the localized surface plasmon of the light-scattering particles 4 are made to resonate with external light and the intensity of the near field light is thereby enhanced.

In the near field light two-dimensional array 50 of the invention, the metal nanoparticles are formed of gold. Accordingly, the invention can provide the near field light two-dimensional array in which the electroconductive member 6 and the light-scattering particles 4 are firmly bonded to each other via the immobilizing layer 2, for example, through gold-thiol bonding of a type of chemical bonding, and the localized surface plasmon of the light-scattering particles 4 can resonate with external light to enhance the intensity of the near field light.

In the near field light two-dimensional array 50 of the embodiment of the invention, the modifying part 5 is an organic molecule having a thiol group, and the thiol group is bonded to the metal nanoparticles. Accordingly, the invention can provide the near field light two-dimensional array in which the regularity in the two-dimensional plane becomes high and the intensity of the near field light is enhanced. In case where gold nanoparticles are used as the metal nanoparticles, the invention provides the near field light two-dimensional array in which the nanoparticles are firmly bonded to the electroconductive member 6 through gold-thiol bonding of strong chemical bonding.

In the near field light two-dimensional array 50 of the embodiment of the invention, the organic molecule of the modifying part 5 has an alkyl chain with from 6 to 20 carbon atoms. Accordingly, the invention can provide the near field light two-dimensional array in which the gap distance Gm is well controlled to enhance the mutual bonding of the light-scattering particles to each other.

In the near field light two-dimensional array 50 of the embodiment of the invention, the immobilizing layer 2 comprises an organic molecule having at least two thiol groups, at least one thiol group is arranged on both one surface and the other surface of the immobilizing layer 2, and the thiol group on the other surface is bonded to the electroconductive member 6. Accordingly, the invention can provide the near field light two-dimensional array in which the immobilizing layer 2 is firmly bonded to the electroconductive member 6.

In the near field light two-dimensional array 50 of the embodiment of the invention, the organic molecule to constitute the immobilizing layer 2 has an alkyl chain with from 6 to 20 carbon atoms. Accordingly, the invention can provide the near field light two-dimensional array which, free from dynamic behavior like that of liquid crystals, is stably immobilized on the immobilizing layer like on the surface of a solid. In addition, the invention can provide the near field light two-dimensional array in which the immobilizing layer thickness Gs and the particle-to-substrate distance Ls are controlled to be uniform and the immobilizing layer 2 is firmly bonded to the electroconductive member 6.

In the near field light two-dimensional array 50 of the embodiment of the invention, the electroconductive member 6 is formed of gold. Accordingly, the invention can provide the near field light two-dimensional array in which the two-dimensional plane regularity is enhanced. In case where an organic molecule having a thiol group is used as the modifying part 5, the gold-thiol bonding serves as strong chemical bonding.

The near field light two-dimensional array 50 of the embodiment of the invention is provided with an external light source from which the external light can focus on the light-scattering particles 4. Accordingly, the invention can provide the near field light two-dimensional array in which the localized surface plasmon of the light-scattering particles 4 can more efficiently resonate with external light.

The production method for the near field light two-dimensional array of the embodiment of the invention comprises a first step of dispersing the light-scattering particles 4 in the solvent 21 to prepare the reaction liquid 22, filling the liquid tank 23 with the reaction liquid 22, and arranging two electrodes 25 and 26 oppositely to each other inside the liquid tank 23 as immersed in the reaction liquid 22 therein, and a second step of applying a voltage to the two electrodes 25 and 26 from the power source 28 connected to the two electrodes 25 and 26 by wiring 27 to thereby move the light-scattering particles 4 in a mode of field migration, whilst moving the position of the liquid level 22a of the reaction liquid 22 relative to the electrode 25 thereby forming light-scattering particle arrays 3 of the two-dimensionally arrayed light-scattering particles 4 on the electrode 25. According to the production method, therefore, a large-area near field light two-dimensional array can be produced easily and inexpensively, which is firmly bonded to the substrate.

In the production method for the near field light two-dimensional array of the embodiment of the invention, the moving speed of the position of the liquid level 22a of the reaction liquid 22 relative to the electrode 25 is at most 0.02 mm/sec. According to the production method, therefore, a large-area near field light two-dimensional array can be produced easily and inexpensively, which is firmly bonded to the substrate.

In the production method for the near field light two-dimensional array of the embodiment of the invention, a volatile solvent is used as the solvent 21 in the first step, and the volatile solvent is evaporated away through voltage application in the second step. According to the production method, therefore, a large-area near field light two-dimensional array can be produced easily and inexpensively, which is firmly bonded to the substrate.

In the production method for the near field light two-dimensional array of the embodiment of the invention, the volatile solvent is any of water, an alcohol, a ketone, an ester, a halogen-containing solvent, an aliphatic hydrocarbon or an aromatic hydrocarbon, or their mixture. According to the production method, therefore, a large-area near field light two-dimensional array can be produced easily and inexpensively, which is firmly bonded to the substrate.

In the production method for the near field light two-dimensional array of the embodiment of the invention, the volatile solvent contains an inorganic salt, an organic salt or both of the two. According to the production method, therefore, a large-area near field light two-dimensional array can be produced easily and inexpensively, which is firmly bonded to the substrate.

The near field light source two-dimensional array and its production method of the invention are not limited to the above-mentioned embodiments. Within the range of the technical scope of the invention, the embodiments thereof can be variously changed and modified. Specific examples of the embodiments are shown in the following Examples. However, the invention should not be limited to these Examples.

### EXAMPLES

### Example 1

### Production Process for Near Field Light Two-Dimensional Array

First, gold nanoparticles having a particle size Fm of about 9 nm were modified with hexanethiol molecules (HEX).

Next, the HEX-modified gold nanoparticles were dispersed in a volatile solvent of n-hexane at a concentration of 5.7×10¹³/ml to prepare a reaction liquid. One surface of a gold thin film-coated glass substrate (having a size of 15 mm×15 mm) was modified with 1,6-hexanedithiol to be an immobilizing layer.

Next, the liquid tank of a near field light two-dimensional array production apparatus was filled with the reaction liquid.

Next, an anode electrode of a carbon electrode and a cathode electrode of the glass substrate with the immobilizing layer and the gold thin film (electroconductive member) formed thereon were immersed in the reaction liquid. The anode electrode and the cathode electrode were so arranged that the electrode surfaces of the two could face each other, and the distance between the electrode surfaces was 1.2 mm. The glass substrate was so arranged that the immobilizing layer thereon could face the counter electrode.

Next, the opening at the top of the liquid tank was closed with a lid.

Next, the power source was controlled to apply a voltage of 1 V between the anode electrode and the cathode electrode. At this time, the opening diameter of the hole of the lid was so controlled that the moving speed to lower the liquid level of the reaction liquid could be 4 mm/hr at room temperature under normal pressure (1 atmosphere, 25° C.).

At the time when the electrodes were completely exposed out of the reaction liquid, the cathode electrode was taken out. Formation of gold nanoparticle arrays on the immobilizing layer of the cathode electrode was visually confirmed.

Next, the cathode electrode with the gold nanoparticle arrays formed thereon was annealed at 40 to 60° C.

Next, the surface of the cathode electrode with the gold nanoparticle arrays formed thereon was washed with running water, and further washed with ultrasonic waves in a hexane solvent.

Thus, the near field light two dimensional array of Example 1 was produced.

### Example 2

A near field light two-dimensional array was produced in the same manner as in Example 1 except that dodecanethiol (DOD) was used in place of HEX.

### Example 3

A near field light two-dimensional array was produced in the same manner as in Example 1 except that hexadecanethiol (HEXD) was used in place of HEX.

### Example 4

A near field light two-dimensional array was produced in the same manner as in Example 2 except that metal nanoparticles having a particle size Fm of from 29 to 30 nm were used.

### Example 5

A near field light two-dimensional array was produced in the same manner as in Example 1 except that an ITO substrate of a transparent electroconductive metal oxide (InTiO) was used in place of arranging the electroconductive thin film of gold (hereinafter referred to as god thin film) on the glass substrate (size of substrate, 15 mm×15 mm). The ITO substrate used here is of a Geomatics' EL specification and has an electroconductivity of 10 Ω/square.

As similar manner as in Example 1, a lid was fitted to cover the opening of the liquid tank, and the diameter of the hole formed in the lid was adjusted. The adjusted hole was smaller than in Example 1 for reducing the solvent evaporation rate herein.

### Example 6

A near field light two-dimensional array was produced in the same manner as in Example 5 except that dodecanethiol (DOD) was used in place of hexanethiol molecules.

### Example 7

A near field light two-dimensional array was produced in the same manner as in Example 5 except that hexadecanethiol (HEXD) was used in place of hexanethiol molecules.

### Comparative Example 1

An electroconductive thin film of gold (hereinafter referred to as gold thin film) was formed on a glass substrate (size of substrate, 15 mm×15 mm), and then the surface of the gold thin film was modified with 1,6-hexanedithiol to form an immobilizing layer.

Next, using HEX-modified gold nanoparticles, a near field light two-dimensional array was formed on the immobilizing layer of the glass substrate with the immobilizing layer and the gold thin film formed thereon according to a known Langmuir method.

### Example 8

A near field light two-dimensional array was produced in the same manner as in Example 5 except that gold nanoparticles having a particle size Fm of from 29 to 30 nm were used.

### Example 9

A near field light two-dimensional array was produced in the same manner as in Example 5 except that gold nanoparticles having a particle size Fm of from 49 to 50 nm were used.

### <SEM Observation>

The near field light two-dimensional arrays of Examples 1 to 3 and Example 7 were observed through SEM.

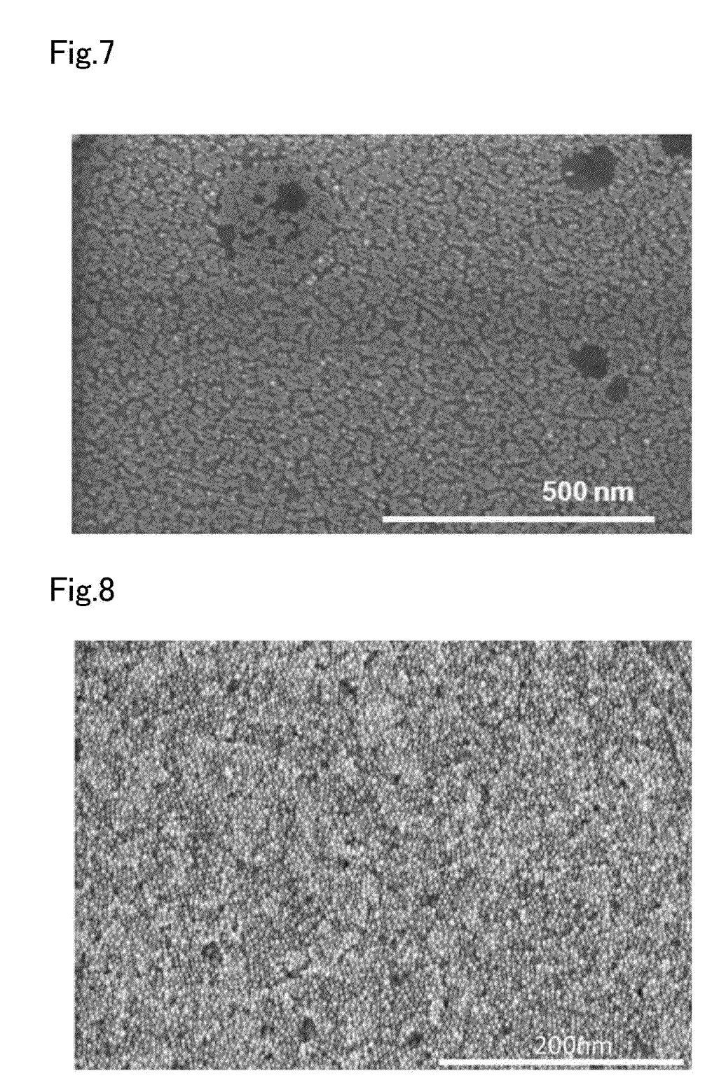

FIG. 7 is a SEM image of the light-scattering particle arrays of the near field light two-dimensional array of Example 1. The particle size Fm of the gold nanoparticles is 9 nm, the particle-to-particle distance Lm is 10.6 nm, and the gap distance Gm between the particles is 1.6 nm.

FIG. 8 is a SEM image of the light-scattering particle arrays of the near field light two-dimensional array of Example 2. The particle size Fm of the gold nanoparticles is 9 nm, the particle-to-particle distance Lm is 11.4 nm, and the gap distance Gm between the particles is 2.4 nm.

The coverage with the metal nanoparticle arrays of gold nanoparticles is 90% or more. Almost the entire range of the substrate having a size of 15 mm×15 mm attained the coverage.

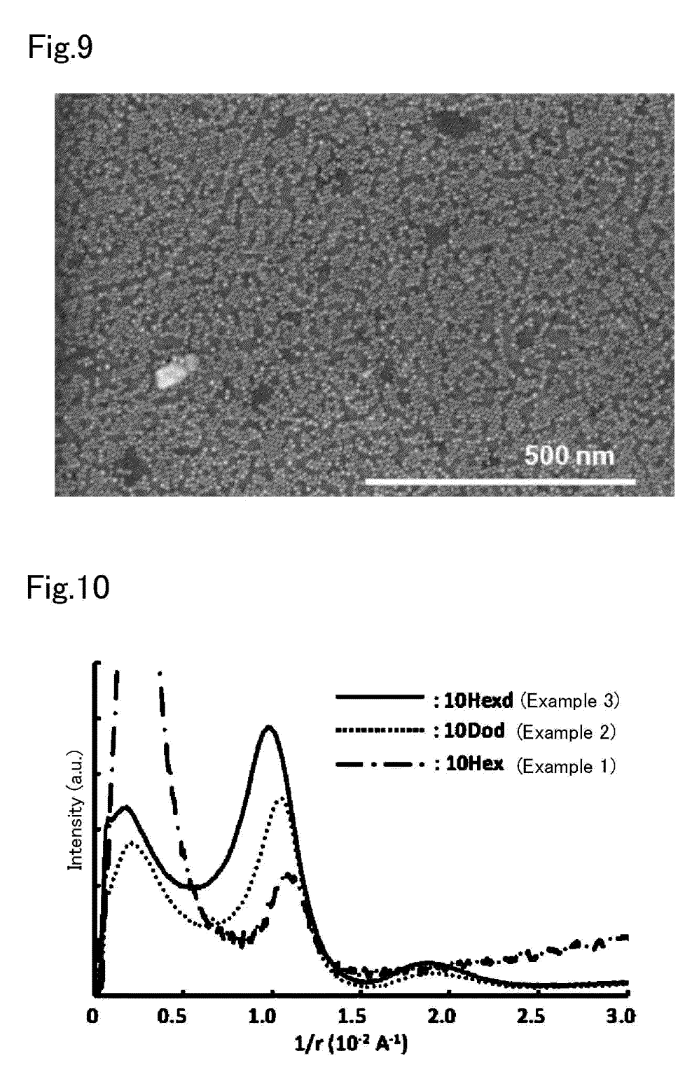

FIG. 9 is a SEM image of the light-scattering particle arrays of the near field light two-dimensional array of Example 3. The particle size Fm of the gold nanoparticles is 9 nm, the particle-to-particle distance Lm is 11.9 nm, and the gap distance Gm between the particles is 2.9 nm. All the arrays have a hexagonal closest packing structure as the nearest neighbor structure.

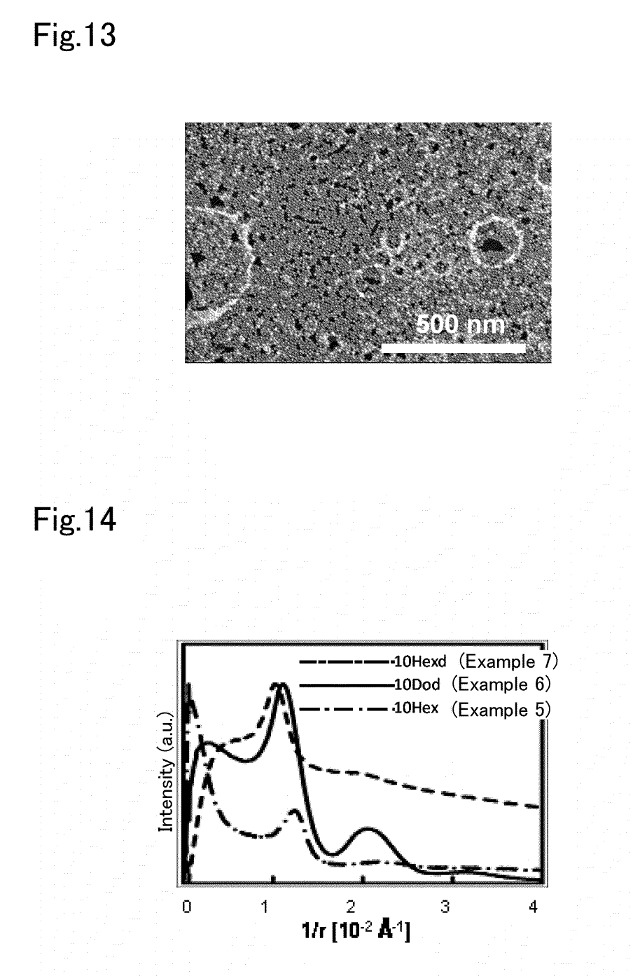

FIG. 13 is a SEM image of the light-scattering particle arrays of the near field light two-dimensional array of Example 7. The particle size Fm of the gold nanoparticles is 9.0 nm, the particle-to-particle distance Lm is 11.9 nm, and the gap distance Gm between the particles is 2.9 nm. The coverage is 92%.

### <Small-Angle Scattering Spectrometry>

Next, the samples were analyzed through small-angle scattering spectrometry. The particle-to-particle distance Lm can be determined more accurately in small-angle scattering spectrometry than in SEM.

FIG. 10 shows the data of small-angle scattering spectra of the near field light two-dimensional arrays of Examples 1 to 3. From the results in FIG. 10, the particle-to-particle distance Lm in the case where HEX, DOD or HEXD was used is 10.8 nm, 11.0 nm and 11.8 nm, respectively. The results indicate that when the length of the alkane molecule is larger, then the particle-to-particle distance Lm becomes longer.

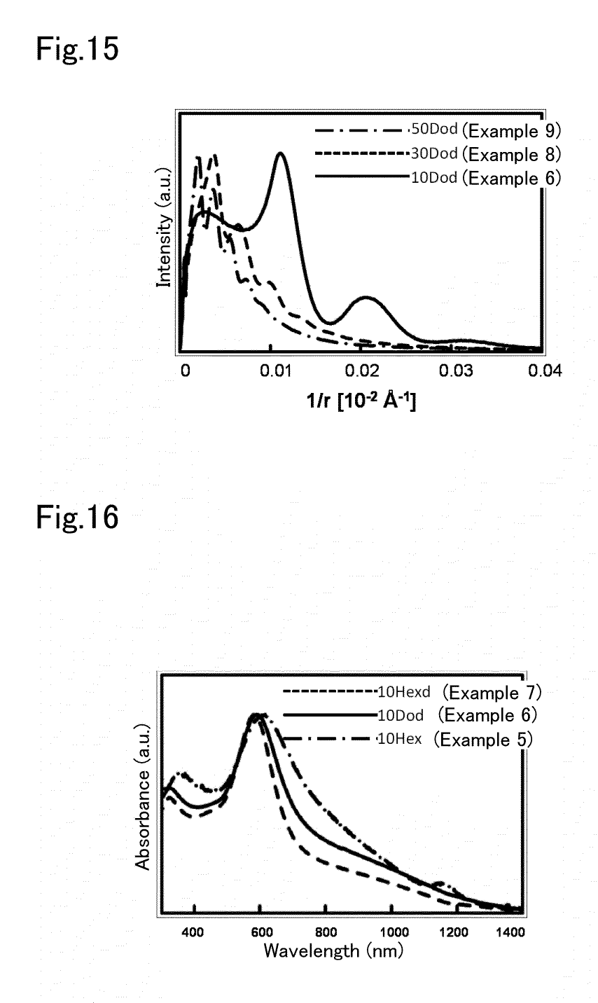

FIG. 14 shows the data of small-angle scattering spectra of the light-scattering particle arrays of the near field light two-dimensional arrays of Examples 5 to 7. FIG. 15 shows the data of small-angle scattering spectra of the light-scattering particle arrays of the near field light two-dimensional arrays of Example 6, Example 8 and Example 9.

From the results in FIG. 14, it is known that the particle-to-particle distance Lm in the case where HEX, DOD or HEXD was used is 9.8 nm, 10.7 nm and 11.0 nm, respectively. The results indicate that when the length of the alkane molecule is larger, then the particle-to-particle distance becomes longer.

This means that the particle-to-particle distance Gm between the gold nanoparticles can be controlled by selecting the modifying molecule, and in particular, it is verified that the carbon number of the alkanethiol molecule and the particle-to-particle distance Gm are proportional to each other.

FIG. 15 shows the data of small-angle scattering spectra of the light-scattering particle arrays of the near field light two-dimensional arrays of Example 6, Example 8 and Example 9. From the results in FIG. 15, it is known that the particle-to-particle distance relative to the particle size Fm, 10 nm, 30 nm and 50 nm is 10.7 nm, 31.4 nm and 50.6 nm, respectively.

The results mean that the gap distance Gm between the gold nanoparticles can be controlled by the particle size Fm, separately verifying the results of the scanning microscopy.

### <Extinction Spectrometry>

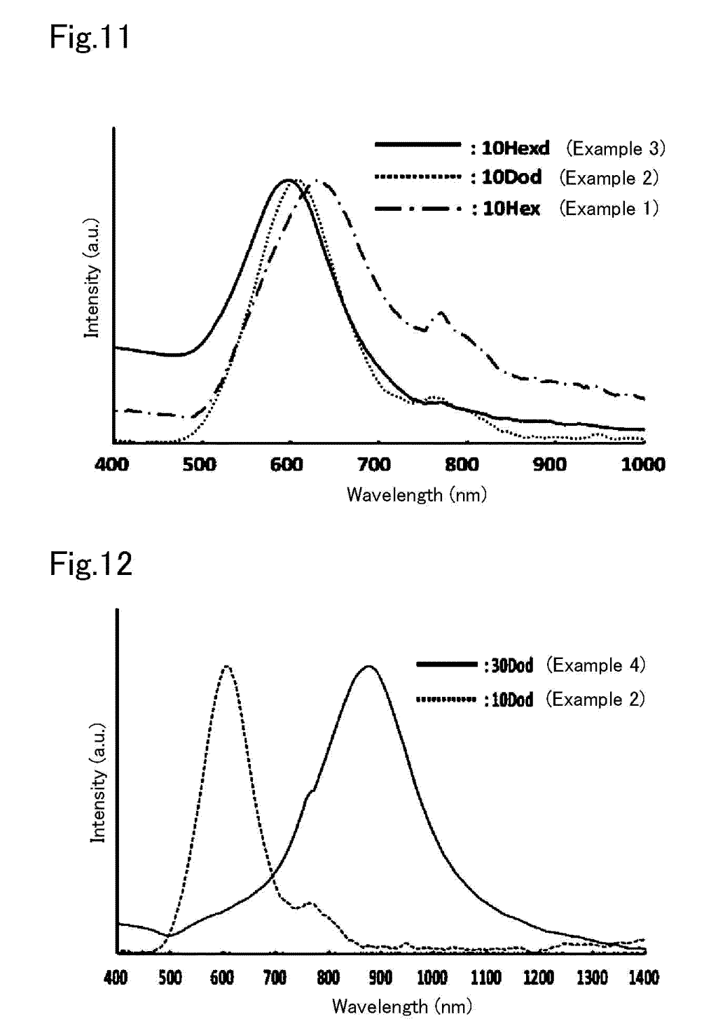

Next, the near field light two-dimensional arrays of Examples 1 to 4 and Examples 5 to 9 were analyzed through extinction spectrometry. FIG. 11 shows the extinction spectra of the light-scattering particle arrays of the near field light two-dimensional arrays of Examples 1 to 3; and FIG. 12 shows the extinction spectra of the light-scattering particle arrays of the near field light two-dimensional arrays of Example 2 and Example 4. FIG. 14 shows the extinction spectra of the near field light two-dimensional arrays of Examples 5 to 7. FIG. 15 shows the extinction spectra of the light-scattering particle arrays of the near field light two-dimensional arrays of Example 6, Example 8 and Example 9. In these, the extinction spectral peak shows the frequency of the localized surface plasmon resonance of the light-scattering particles (gold nanoparticles) that constitute the light-scattering particle arrays.

As shown in FIG. 11, in case where the particle size Fm of the gold nanoparticles was immobilized to be 10 nm and when the modifying molecule was changed to HEX, DOD or HEXD, then the extinction spectral peak (frequency of localized surface plasmon resonance) changed from 630 nm to 599 nm (blue-shifting). This indicates that by changing the size of the modifying molecule, the frequency of localized surface plasmon resonance can be controlled.

As shown in FIG. 12, in case where the modifying molecule was immobilized to be DOD and when the particle size Fm of the gold nanoparticles was changed from 10 nm to 30 nm, then the extinction spectral peak (frequency of localized surface plasmon resonance) changed from 599 nm to 880 nm (red-shifting).

As shown in FIG. 16, in case where the particle size Fm of the gold nanoparticles was immobilized to be 10 nm and when the modifying molecule was changed to HEX, DOD or HEXD, then the extinction spectral peak (frequency of localized surface plasmon resonance) changed from 615 nm to 582 nm (blue-shifting). This indicates that, even on the ITO substrate, the frequency of localized surface plasmon resonance can be controlled by changing the size of the modifying molecule.

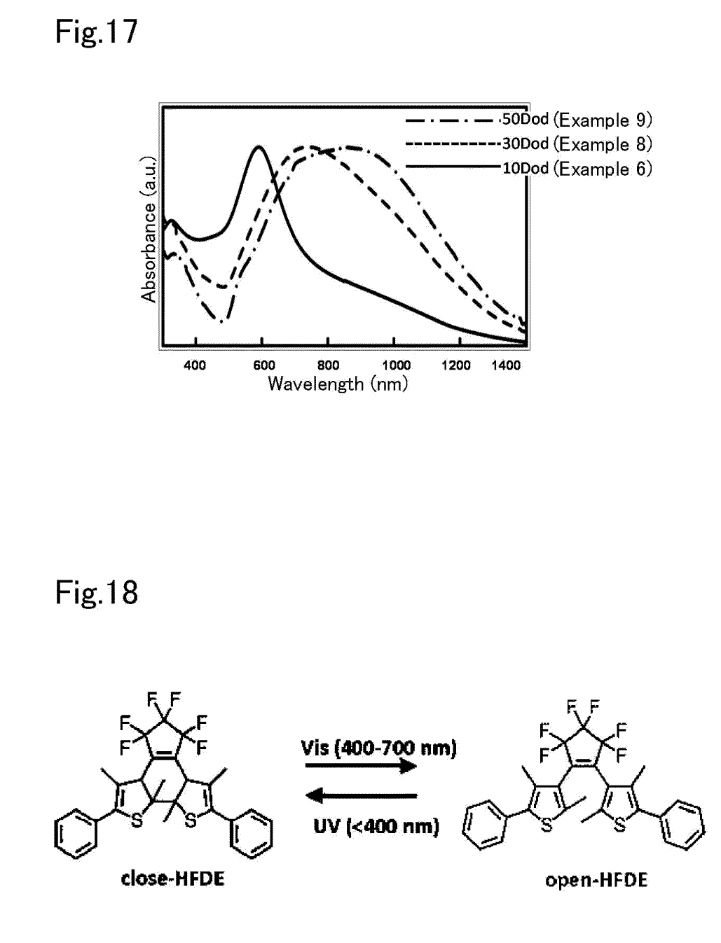

Further, as shown in FIG. 17, in case where the modifying molecule was immobilized to be DOD and when the particle size Fm of the gold nanoparticles was changed from 10 nm to 50 nm, then the extinction spectral peak (frequency of localized surface plasmon resonance) changed from 592 nm to 850 nm (red-shifting) even on the ITO substrate.

From the above results, it is known that the desired localized surface plasmon resonance frequency can be attained by suitably defining the gap distance Gm between the gold nanoparticles and the particle size Fm of the gold nanoparticles. The dependency is suggested also in Non-Patent Document 20, and was verified in a simplified manner in these Examples.

### <Measurement of Mechanical Strength (Chemical Bond Strength)>

The mechanical strength between the gold nanoparticles and the electroconductive member (gold thin film on glass substrate) through chemical bonding to the electroconductive substrate was confirmed by ultrasonic washing in a hexane solvent (24.8 kHz, 5 minutes).

The near field light two-dimensional array of Comparative Example 1 remained only 18%. On the other hand, the near field light two-dimensional array of Example 1 remained 71%. Similarly, the near field light two-dimensional array of Example 5 remained 90%.

The measured results of the mechanical strength confirmed the chemical bonding of the light-scattering particle arrays to the electroconductive member via the immobilizing layer, verifying the effect of the durability of maintaining the mechanical strength even after ultrasonic washing in solvent.

The mechanical strength is a technical point important for light-scattering particle arrays that are exposed to the flow of a reaction solution in a microreactor flow channel in a case where the near field light two-dimensional array is arranged in a microreactor flow channel for photochemical reaction therethrough.

From the above results, it is known that the near field light two-dimensional array of the invention can be formed even on an electroconductive film formed on an insulating substrate or even on an ITO substrate such as a transparent electrode, so far as the surface thereof is an electroconductive substrate surface.

### Effect of Photochemical Reaction Using Near Field Light Two-Dimensional Array

### Example 10

Photochemical reaction was confirmed, using the near field light two-dimensional array.

First produced was a microreactor arranged in the flow channel of a near field light two-dimensional array using 30-nm gold nanoparticles modified with dodecanethiol.

First, a transparent substrate of PDMS (polydimethylsiloxane) was prepared.

Next, according to an in-print method, a microchannel groove pattern hazing a size of 1 mm width×50 μm height×5 mm length was formed on one surface of a transparent substrate, and two holes were formed to connect the other surface of the transparent substrate with the microchannel.

Next, the substrate of the near field light two-dimensional array was bonded to the transparent substrate in such a manner that the near field light two-dimensional array could be arranged inside the microreactor groove, and they were mechanically immobilized.

As the photochemical reaction material, used was hexafluorodiarylethene.

FIG. 18 shows photochemical reaction of hexafluorodiarylethene.

As shown in FIG. 18, hexafluorodiarylethene in a closed state (hereinafter referred to as close-HFDE) generally undergoes photochemical reaction when irradiated with visible light of from 400 to 700 nm to change to hexafluorodiarylethene in an open state (hereinafter referred to as open-HFDE). The open-HFDE generally undergoes photochemical reaction when irradiated with UV light of at most 400 nm to change to close-HFDE.

First, a dispersion prepared by dispersing close-HFDE in a solvent was put into the microreactor.

Next, from the light source for the near field light two-dimensional array, the dispersion was irradiated with light having a wavelength of from 700 to 1100 nm, which is the resonance frequency of the near field light two-dimensional array using 30-nm gold nanoparticles modified with dodecanethiol.

At the same time, the dispersion was sucked through a syringe pump. The flow rate was about 0.06 mL/min.

Next, the dispersion in the syringe pump was analyzed to identify the chemical substances contained in the dispersion.

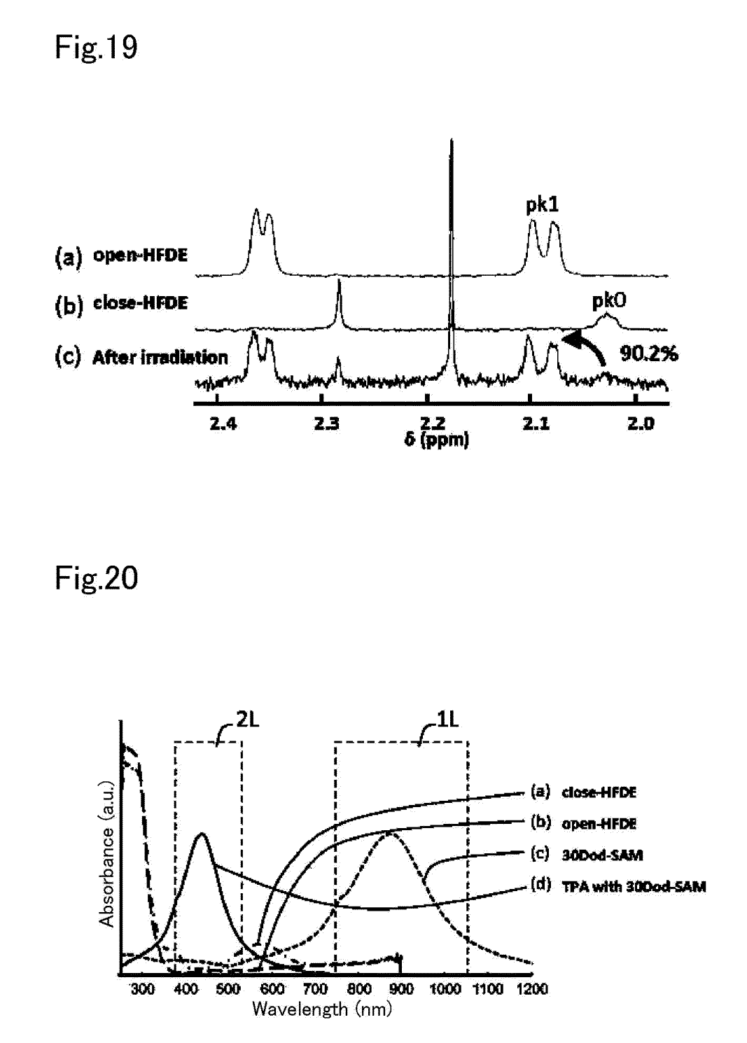

FIG. 19 shows NMR spectra. FIG. 19(a) is the NMR spectrum of open-HFDE; FIG. 19(b) is the NMR spectrum of the reaction product (close-HFDE) in the dispersion before photoirradiation; and FIG. 19(c) is the NMR spectrum of the product in the dispersion after photoirradiation.

90.2% of close-HFDE was converted into open-HFDE.

FIG. 20 shows absorption spectra of hexafluorodiarylethene (HFDE). FIG. 20(a) is the absorption spectrum of close-HFDE; FIG. 20(b) is the absorption spectrum of open-HFDE; FIG. 20(c) is the absorption spectrum (extinction spectrum) of the array where the gold nanoparticles having a particle size of 30 nm were self-organized (hereinafter referred to as 30 Dod-SAM): and FIG. 20(d) is the spectrum of the near field light in two-photon excitation (hereinafter referred to as TPA with 30 Dod-SAM).

Here, the wavelength region (740 to 1050 nm) of light for irradiation to 30 Dod-SAM is indicated by 1 L. The wavelength region (380 to 530 nm) of the near field light in two-photon excitation having occurred through photoirradiation on the wavelength range of 1 L is indicated by 2 L.

As shown in FIG. 20, the irradiation region with the near field light based on the two-photon excitation wavelength overlaps with the absorption wavelength of close-HFDE in the wavelength region of from 450 nm to 560 nm, and therefore, it is considered that the two-photon reaction would have resulted from the strong near field light generated by the gold nanoparticle two-dimensional array.

This verifies efficient photochemical reaction attained by the near field light two-dimensional array.

### Solar Cell

### Example 11

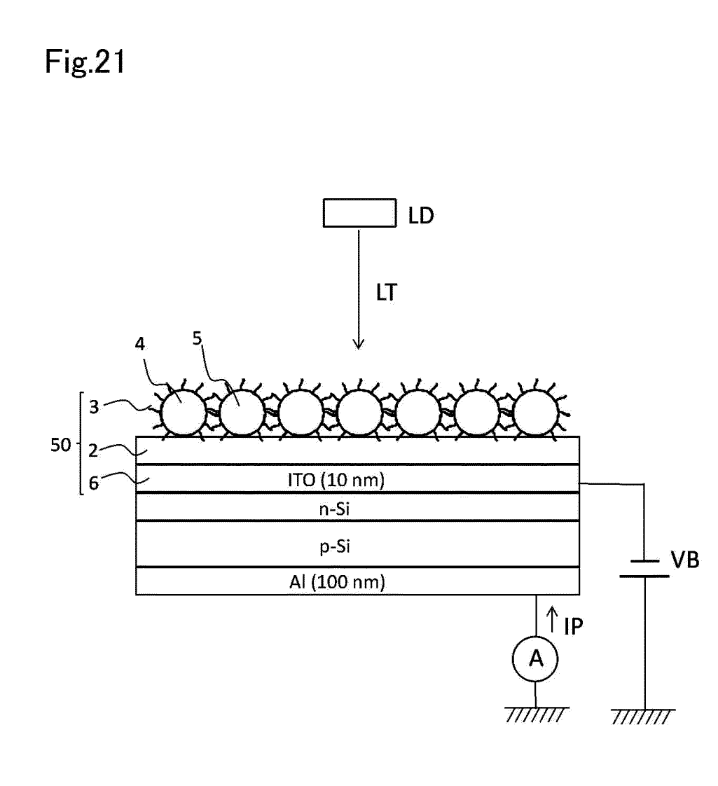

It is described an example of a solar cell to which the invention is applied. As shown in FIG. 21, on a solar cell structure comprising a p-type silicon substrate (having a specific resistivity of from 0.015 to 0.017 Ωcm) and, as laminated thereon, an n-type silicon (of which the doping dose is on the same level as that of the p-type silicon), an ITO film was laminated as the electroconductive layer 6 through sputtering evaporation of 10 nm, and further, a hexanedithiol layer 2 was laminated thereon. According to the above-mentioned method and using 10-nm gold nanoparticles 4 chemically modified with dodecanethiol, a near field light two-dimensional array 50 was formed. Since the near field light two-dimensional array 50 is spaced from the solar cell layer by 10 nm, the near-field light generating region is over 10 nm; and consequently, the near field light two-dimensional array 50 functions as a two-dimensional array-type localized surface plasmon resonator. In other words, the near field light generated by the near field light two-dimensional array again returns back to the propagating light and is absorbed by the solar cell layer. The two-dimensional array-type localized surface plasmon resonator comprising the 10-nm gold nanoparticles 4 chemically modified with dodecanethiol has a resonant frequency at around 600 nm, and contributes toward enhancing the absorption efficiency of the solar cell.

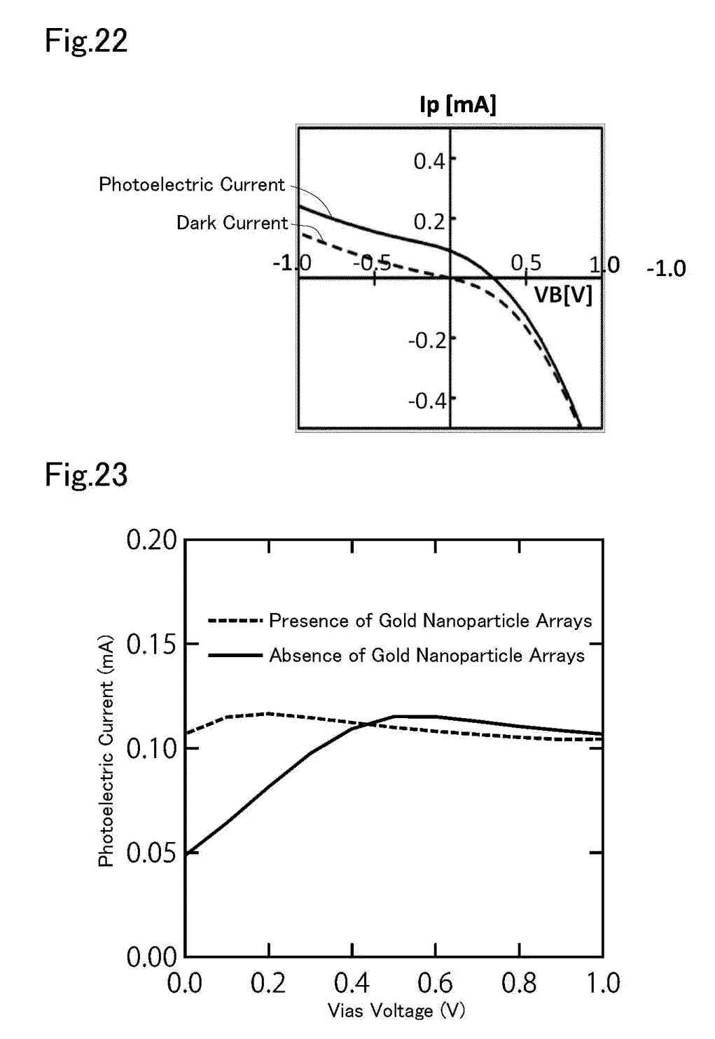

FIG. 22 shows the characteristics of the solar cell shown in FIG. 21. A reference case with no two-dimensional array-type localized surface plasmon resonator is also shown. As the light, used was commercial white LED that is a pseudo-sunlight source. The expression “photoelectric current” means the current-voltage characteristic with photoirradiation; and “dark current” means the current-voltage characteristic without photoirradiation. In particular, the current value with no voltage application is referred to as a short-circuit current well used in evaluating solar cell performance. As the value to be obtained by subtracting the dark current, an open circuit current of 90 μA can be obtained in a square of 5 mm×5 mm, though the coverage in the solar cell having the two-dimensional array-type localized surface plasmon resonator is not full but is about 60%. From the solar cell not having the two-dimensional array-type localized surface plasmon resonator, the open circuit current is 56 μA; and this means that the open circuit current is increased by about two times by adding the two-dimensional array-type localized surface plasmon resonator. It is known that the characteristics of the solar cell are enhanced.

### Optical Sensor

### Example 12

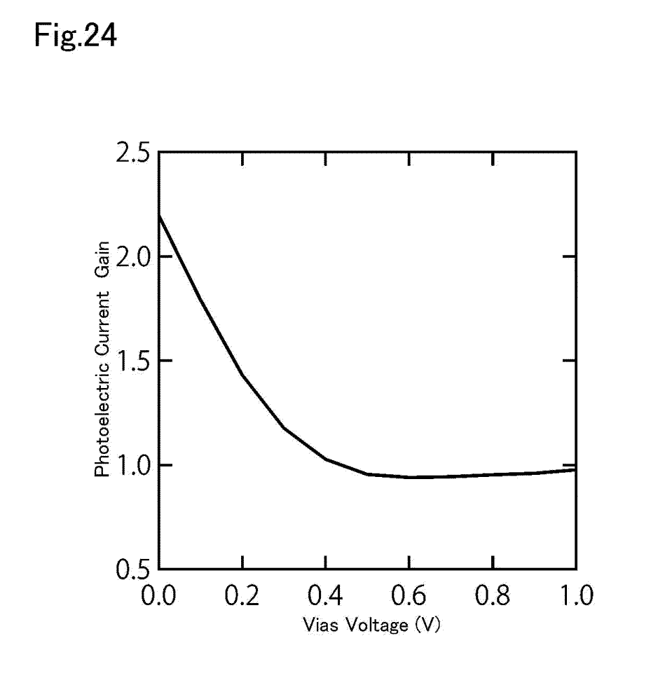

The same device structure as in FIG. 21 was tested in point of the effect for an optical sensor. Since the near field light two-dimensional array 50 is spaced from the pn junction of the optical sensor layer by at least 10 nm, the near-field light generating region is over 10 nm; and consequently, the near field light two-dimensional array 50 functions as a two-dimensional array-type localized surface plasmon resonator. The near field light generated by the near field light two-dimensional array again returns back to the propagating light and is absorbed by the optical sensor layer. The two-dimensional array-type localized surface plasmon resonator comprising the 10-nm gold nanoparticles 4 chemically modified with dodecanethiol has a resonant frequency at around 600 nm, and contributes toward enhancing the absorption efficiency of the optical sensor. As shown in FIG. 23, as compared with the case not having the two-dimensional array-type localized surface plasmon resonator, the photoelectric current value is large at the reverse bias of 0.4 V or less. FIG. 24 shows the specific gain in the presence or absence of the two-dimensional array-type localized surface plasmon resonator. At the reverse bias of 0.4 V or less, the specific photoelectric current gain is 1 to 2 times, while at the reverse bias of 0.4 V or more, the specific photoelectric current gain is around 1; and from this, it is known that the sensitivity of the optical sensor is increased.

### Biosensor

### Example 13

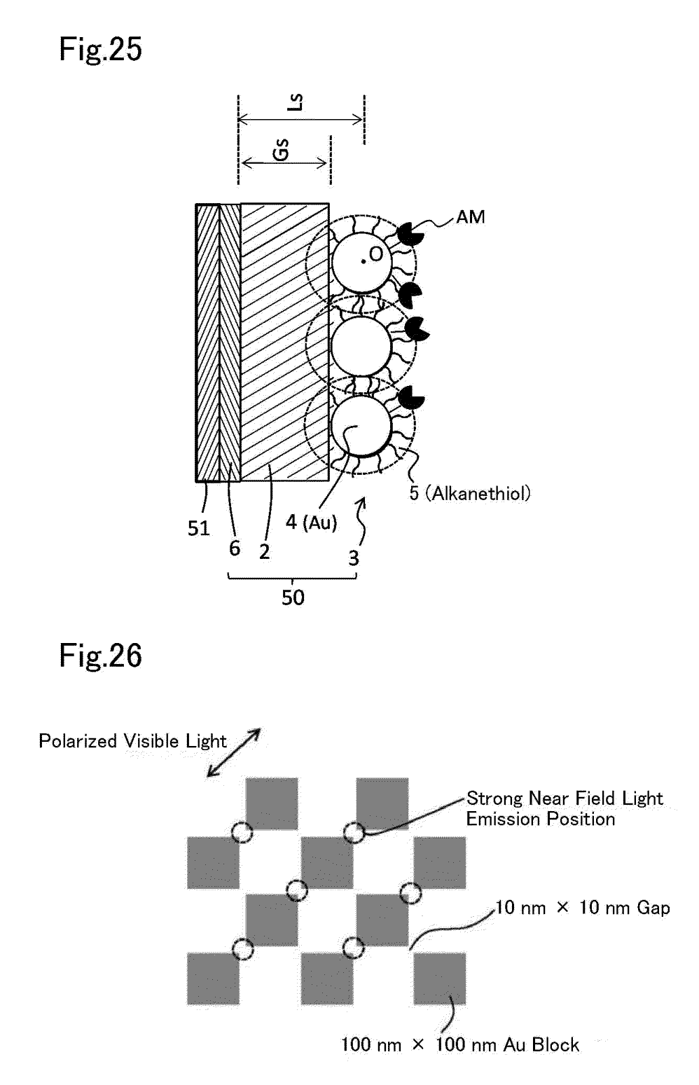

FIG. 25 shows the configuration of a biosensor that comprises a plasmon resonator. This does not differ from the near field light two-dimensional array shown in FIG. 5 except that the antigen AM is added to the light-scattering particles. As shown in Patent Document 4, it is easy to add the antigen to gold nanoparticles to be the light-scattering particles, and the patent Document discloses that the reaction with an antibody can be detected at high sensitivity based on the peak intensity of the plasmon resonance or on the wavelength shifting. The modifying molecules 5 on the light-scattering particles 4 are dense between the light-scattering particles 4, but are somewhat non-dense in the other area. Accordingly, there remains a space that accepts the antigen AM binding thereto. In addition, as compared with that in Patent Document 4, the density of the light-scattering particles in the near field light two-dimensional array of the present invention is high, and therefore, a biosensor having a higher sensitivity can be produced herein than in Patent Document 4. As AM, any other molecule containing a DNA sequence or the like can be selected in addition to the antigen comprising protein or the like, and the invention is applicable also to a biosensor for detecting a DNA having a specific sequence.

### INDUSTRIAL APPLICABILITY

The near field light two-dimensional array of the invention is usable as a large-area near field light two-dimensional array firmly immobilized on a substrate through chemical bonding or the like, and is applicable to synthetic industry using microreactors for efficiently producing chemical products by utilizing the array for the photochemical reaction in microreactors.

### DESCRIPTION OF REFERENCE NUMERALS

2 Immobilizing Layer
2a One Surface
3 Light-Scattering Particle Array
4 Light-Scattering Particle
5 Modifying Part
6 Electroconductive Member
6a One Surface
8 Domain
21 Solvent
22 Reaction Liquid
22a Liquid Level
23 Liquid Tank
24 Lid
24c Hole
25, 26 Electrode
27 Wiring
28 Power Source
29 Air-Liquid Interface
50 Near field Light Two-Dimensional Array
51 Substrate
Fm Particle Size
Gm Gap Distance (Distance)
Lm Particle-to-Particle Distance
O Center
Ls Particle-to-Substrate Distance
Gs Thickness of Immobilizing Layer
NF, NFO2, NFO3 Near field Light

1. A near field light two-dimensional array comprising an electroconductive member, an immobilizing layer formed on one surface of the electroconductive member and a plurality of light-scattering particles arranged on one surface of the immobilizing layer, and enabling in-plane light emission through the near field light from the light-scattering particles, wherein:
the light-scattering particles have a particle size of from 1 to 100 nm;
the light-scattering particles are arrayed in a lattice arrangement and spaced equally from each other, and the distance between the adjacent light-scattering particles is not larger than the particle size; and
the localized surface plasmon of the light-scattering particles can resonate with external light.

2. The near field light two-dimensional array as claimed in claim 1, wherein the thickness of the immobilizing layer is 10 nm or less.

3. The near field light two-dimensional array as claimed in claim 1, wherein the distance between the light-scattering particles is from 1 to 10 nm.

4. The near field light two-dimensional array as claimed in claim 1, wherein the light-scattering particles are bonded to each other via a modifying part arranged on the surface thereof.

5. The near field light two-dimensional array as claimed in claim 1, wherein the light-scattering particles are metal nanoparticles.

6. The near field light two-dimensional array as claimed in claim 5, wherein the metal nanoparticles are formed of gold.

7. The near field light two-dimensional array as claimed in claim 4, wherein the modifying part is an organic molecule having a thiol group, and the thiol group is bonded to the metal nanoparticles.

8. The near field light two-dimensional array as claimed in claim 7, wherein the organic molecule of the modifying part has an alkyl chain with from 6 to 20 carbon atoms.

9. The near field light two-dimensional array as claimed in claim 1, wherein the immobilizing layer comprises an organic molecule having at least two thiol groups, at least one thiol group is arranged on both one surface and the other surface of the immobilizing layer, and the thiol group on the other surface is bonded to the electroconductive member.

10. The near field light two-dimensional array as claimed in claim 9, wherein the organic molecule constituting the immobilizing layer has an alkyl chain with from 6 to 20 carbon atoms.

11. The near field light two-dimensional array as claimed in claim 1, wherein the electroconductive member is formed of gold.

12. The near field light two-dimensional array as claimed in claim 1, wherein an external light source is disposed so that the external light can focus on the light-scattering particles.

13. A production method for a near field light two-dimensional array comprising:
a first step of dispersing light-scattering particles in a solvent to prepare a reaction liquid, filling a liquid tank with the reaction liquid, and arranging two electrodes oppositely to each other inside the liquid tank as immersed in the reaction liquid therein, and
a second step of applying a voltage to the two electrodes from a power source connected to the two electrodes by wiring to thereby move the light-scattering particles in a mode of field migration, whilst moving the position of the liquid level of the reaction liquid relative to the electrode thereby forming light-scattering particle arrays of the two-dimensionally arrayed light-scattering particles on the electrode.

14. The production method for a near field light two-dimensional array as claimed in claim 13, wherein the moving speed of the position of the liquid level of the reaction liquid relative to the electrode is 0.02 mm/sec or less.

15. The production method for a near field light two-dimensional array as claimed in claim 13, wherein:
a volatile solvent is used as the solvent in the first step, and
the volatile solvent is evaporated away through voltage application in the second step.

16. The production method for a near field light two-dimensional array as claimed in claim 15, wherein the volatile solvent is any of water, an alcohol, a ketone, an ester, a halogen-containing solvent, an aliphatic hydrocarbon or an aromatic hydrocarbon, or their mixture.

17. The production method for a near field light two-dimensional array as claimed in claim 15, wherein the volatile solvent contains an inorganic salt, an organic salt or both of the two.

18. A two-dimensional array-type localized surface plasmon resonator provided with the near field light two-dimensional array of claim 1.

19. A solar cell provided with the two-dimensional array-type localized surface plasmon resonator of claim 18.

20. An optical sensor provided with the two-dimensional array-type localized surface plasmon resonator of claim 18.

21. A biosensor provided with the two-dimensional array-type localized surface plasmon resonator of claim 18.
